(19) United States
(12) Patent Application Publication
(10) Pub. No.: US 2020/0333394 A1
(43) Pub. Date: Oct. 22, 2020

(54) WAVEFORM SEPARATION FOR RESOLUTION LIMITED OPTICAL PROBING TOOLS

(71) Applicant: FEI Company, Hillsboro, OR (US)

(72) Inventors: Tenzile Berkin Cilingiroglu, Fremont, CA (US); Neel Leslie, Fremont, CA (US); Seema Somani, Fremont, CA (US); Prasad Sabbineni, Fremont, CA (US)

(73) Assignee: FEI Company, Hillsboro, OR (US)

(21) Appl. No.: 16/388,410

(22) Filed: Apr. 18, 2019

(51) Int. Cl. G01R 31/308; H04B 10/071; G01R 1/07

(52) U.S. Cl. CPC G01R 31/308; G01R 1/071; H04B 10/071

(57) ABSTRACT

Methods and systems for optically determining the performance of active components of a device under test (DUT). A portion of the DUT that includes a target active component and an additional active component is illuminated and reflected energy from the target active component and the additional active component is detected by one or more sensors. An analog signal that corresponds to the reflected energy is generated by a processor. An estimated target signal determined based on the analog signal and the second analog signal, where the estimated target signal corresponds to an estimated component of the analog signal that is attributable to the target reflected energy reflected by the target active component. The estimated target signal is then used to determine the performance of the target active component of the DUT.

### BACKGROUND OF THE INVENTION

Laser Voltage Probing (LVP) is an optical probing technique that allows the voltage changes of an active component of a device under test (DUT) to be measured over time. To test the functionality of an active component of a DUT using LVP, a region of interest of the DUT that includes the active component is illuminated by a focused laser beam. The reflection of the laser beam from the active component is then detected and converted into an analog signal, and the modulation pattern exhibited by the analog signal is analyzed to determine whether the active component is functioning properly. In this way, LVP represents a contactless and destruction-free technique for measuring the functionality of DUT components.

However, as the size of circuit components continue to shrink in accordance with Moore's law, the ability to focus the laser beam has become a fundamental limitation to the usefulness of LVP. Because active components in contemporary high-performance circuits are often far smaller than the diameters of the regions illuminated during LVP, tens or even hundreds of independent active components may be illuminated by the focused laser beam. This means that during LVP of contemporary high-performance circuits, the analog signal that is generated from detected reflected energy often exhibits an amalgamation of many independent modulation patterns that each correspond to individual active components. This amalgamation of modulation patterns makes it impossible to identify individual modulation patterns within the analog signal, which in turn makes it impossible to evaluate the functionality of individual DUT components using current techniques.

Currently, this problem has been addressed by hardware modifications, such as higher numerical aperture lenses, lower wavelength laser sources, etc. However, these modifications will not be enough to cope with the rate of shrinkage in transistor dimensions in the coming years.

### SUMMARY OF THE INVENTION

Methods and systems for optically determining the performance of active components of a device under test (DUT) according to the present disclosure include illuminating a portion of the DUT with a focused laser beam, where the portion of the DUT that the focused laser beam illuminates includes a target active component and an additional active component. First reflected energy from the DUT is detected by one or more sensors, and a first analog signal that corresponds to the first reflected energy is generated by a processor. The first reflected energy includes a first portion of the target reflected energy from the target active component and a first portion of additional reflected energy from the additional active component.

Additionally, second reflected energy from the DUT is also detected by one or more sensors, and a second analog signal that corresponds to the second reflected energy is generated by the processor. The second reflected energy includes a second portion of the target reflected energy from the target active component and a second portion of the additional reflected energy from the additional active component. The processor is further configured to determine an estimated target signal based on the first analog signal and the second analog signal. The estimated target signal corresponds to an estimated component of the first analog signal and the second analog signal that is attributable to the target reflected energy reflected by the target active component. Determining the estimated target signal comprises applying an algorithm to the first analog signal and the second analog signal to generate a decomposition relationship, and then utilizing the decomposition relationship to generate the estimated target signal. Once the estimated target signal is generated, it is used to determine the performance of the target active component of the DUT.

### BRIEF DESCRIPTION OF THE DRAWINGS

The detailed description is described with reference to the accompanying figures. In the figures, the left-most digit(s) of a reference number identify the figure in which the reference number first appears. The same reference numbers in different figures indicates similar or identical items.

FIG. 1 illustrates example optical testing setups for determining the performance of a target active component of a device under test (DUT) using laser voltage probing.

FIG. 2 illustrates example optical testing setups for determining the performance of a target active component of a DUT using time resolved emission testing.

FIG. 3 is a flow diagram of an illustrative process for determining the performance of a target active component of a DUT.

FIG. 4 depicts a diagram that illustrates a sample process determining the estimated reflected signals from a plurality of analog signals.

FIG. 5 depicts a diagram that illustrates a sample process for determining the performance of one or more active components of a DUT.

FIG. 6 is a flow diagram of an illustrative process for determining the performance of one or more active components of a DUT.

Like reference numerals refer to corresponding parts throughout the several views of the drawings.

### DETAILED DESCRIPTION OF EMBODIMENTS

Methods and systems for optically probing contemporary high-performance circuits to determine the performance of individual active components are disclosed. More specifically, the disclosure includes methods and systems that improve upon prior optical probing technology, enabling the evaluation of circuit component performance in contemporary circuits that would not otherwise be able to be evaluated optically due to hardware limitations. For example, in circuits were the diameters of individual circuit components are so small that a plurality of active components are illuminated by a focused laser beam, the technical improvements disclosed herein overcome the cross-talk between the plurality of reflected signals from each of the illuminated active components so that the particular signal reflected by a target active component can be evaluated individually.

Generally, in the figures, elements that are likely to be included in a given example are illustrated in solid lines, while elements that are optional to a given example are illustrated in broken lines. However, elements that are illustrated in solid lines are not essential to all examples of the present disclosure, and an element shown in solid lines may be omitted from a particular example without departing from the scope of the present disclosure.

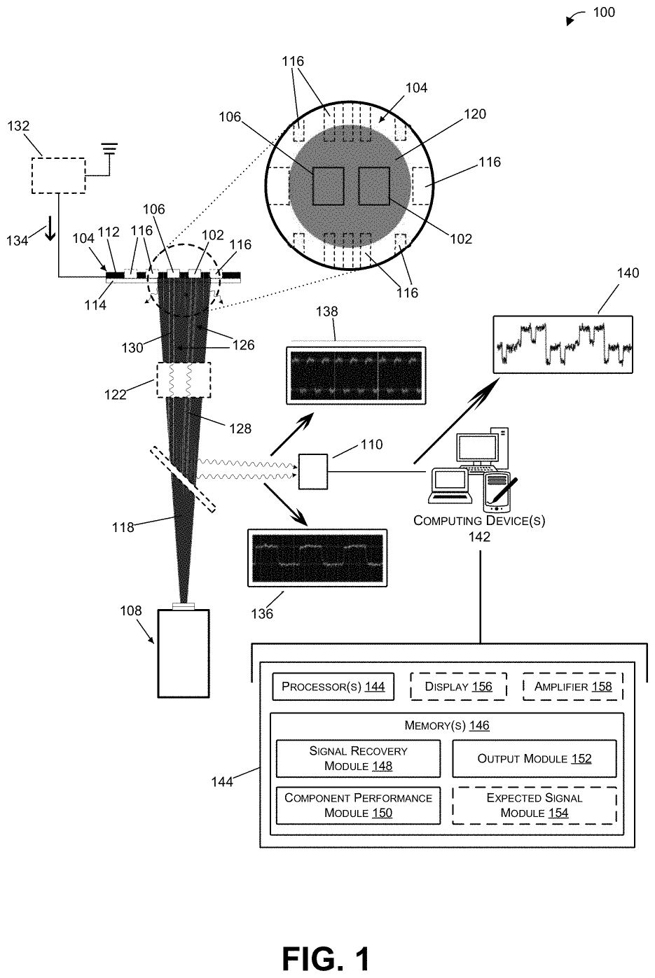

FIG. 1 is an illustration of example optical testing setup(s) 100 for determining the performance of a target active component 102 of a device under test (DUT) 104. Specifically, FIG. 1 is an illustration of example optical testing setup(s) 100 for determining the performance of a target active component 102 of a device under test (DUT) 104 using laser voltage probing (LVP). According to the present disclosure, the optical testing setup(s) 100 include a DUT 104 having a target active component 102 and an additional active component 106, a laser source 108, and/or one or more sensors 110.

The DUT 104 may correspond to an electric circuit and/or integrated circuit that is being optically probed by the optical testing setup(s) 100. For example, the DUT 104 may be a CMOS device that is being optically probed as part of a debugging process. The target active component 102 and additional active component 106 correspond to components of the DUT 104, such as a transistor, a diode, a resistor, a capacitor, a conductive pathway(s) therebetween, a constituent element thereof, etc. In some embodiments, the active component 102 and additional active component 106 may be constituent elements of the same component. For example, the target active component 102 may be a gate (e.g., p-gate, an n-gate, etc.) of a transistor, and the additional active component 106 may be a drain (e.g., p-drain, an n-drain, etc.) of the same transistor of the DUT 104.

The DUT 104 is composed of an upper layer 112, and a substrate base layer 114. As shown in FIG. 1, that upper base layer 112 includes the target active component 102 and the additional active component 106. Additionally, in some embodiments, the upper layer 112 optionally includes one or more other active components 116, such as transistors, diodes, resistors, capacitors, conductive pathways therebetween, constituent elements thereof, etc. The substrate base layer 114 may be partially or completely formed of silicon. In some embodiments, portions of the substrate base layer 114 may be doped or otherwise modified to form constituent elements of the target active component 102, the additional active component 106, and/or one or more other active component(s) 116. Alternatively, in some embodiments the DUT 104 may not include a substrate base layer 114 and/or the substrate base layer 114 may be substantially removed prior to testing.

The laser source 108 is configured to direct a focused laser beam 118 onto the DUT 104 to illuminate a region of the DUT 120. Example laser sources 108 include, but are not limited to, a pulsed laser, a pulse mode-locked laser, a continuous-wave laser source, or a combination thereof (e.g., a dual laser source). As shown in FIG. 1, the laser source 108 is configured to direct the focused laser beam 118 to pass through the substrate base layer 114 (e.g., a silicon substrate) and to strike and/or illuminate one or more active components of the DUT 120 (e.g., target active component 102, additional active component 106, and/or one or more other active component(s) 116). In some embodiments, the substrate base layer 114 may be shaved or otherwise thinned to allow the focused laser beam 118 to more easily pass through the substrate base layer 114.

In some embodiments, the optical testing setup(s) 100 may further include one or more focusing structures 122, such as a lens. For example, an optical testing setup 100 may include a field immersion lens that is configured to cause the focused laser beam 118 to illuminate the region of the DUT 120. The illuminated region of the DUT 104 may include the target active component 102, the additional active component 106, and/or one or more other active component(s) 116. For example, in contemporary high-performance circuits, the diameter of individual active components may be less than or equal to 5 nm and/or 10 nm. Where the DUT 104 is such contemporary high-performance circuit the illuminated region of the DUT 120 may include 2, 4, 10, 20, 100, 200, or more individual active components.

FIG. 1 further shows example optical testing setup(s) 100 including one or more sensors 110 configured to detect reflected energy 126. Reflected energy 126 that corresponds to energy that is reflected from the active components within the illuminated region of the DUT 120. The reflected energy 126 may include target reflected energy 128 that corresponds to energy that is reflected from the target active component 102, and additional reflected energy 130 that corresponds to energy that is reflected from the additional active component 106. For example, an optical testing setup 100 may include a photodetector (e.g., an avalanche photodiode, a single pixel detector, a multi-pixel detector, etc.) that is configured to detect the reflected energy 126 from the target active component 102, the additional active component 106, and/or one or more other active component(s) 116. In such an embodiment, the reflected energy 126 may be detected by the one or more sensors 110 comprises reflected energy from each active component that is within the illuminated region of the DUT 120.

Additionally, FIG. 1 illustrates example optical testing setup(s) 100 as optionally including an electrical signal source 132 configured to provide an electric signal 134 to the DUT 104. The electric signal 134 causes one or more of the target active component 102, the additional active component 106, and/or one or more other active component(s) 116 to be switched between an on state and an off state, causing the voltage of each of the target active component 102, the additional active component 106, and/or one or more other active component(s) 116 to be modulated over time. Additionally, the reflectivity of an active component and/or the refraction index of a portion of the substrate base layer 114 proximate to an active component in correspondence with the voltage of the active component. This causes the reflected energy 126 to be modulated in correspondence with the voltage of the associated active component(s). For example, FIG. 1 illustrates that the target reflected energy 128 as being modulated according to a target signal pattern 136, and the additional reflected energy 130 as being modulated according to an additional signal pattern 138.

As shown in FIG. 1, at least a portion of the reflected energy 126 is incident upon and/or is detected by the one or more sensors 110. However, because present technology sensors are not able to differentiate between the target reflected energy 128, the additional reflected energy 130, and/or other reflected energy from the other active component(s) 116, the information output by the one or more sensors 110 comprises an amalgamation of multiple different signal patterns 140. In other words, when there are more than one active components within the illuminated region of the DUT 120, the one or more sensors 110 output a signal that is a combination of the individual signal patterns from each of the active components within the illuminated region of the DUT 120. This combination of multiple independent signal sources is called cross talk. Because of this cross talk, when contemporary high-performance circuits are probed by an optical testing setup 100 the signal output by the one or more sensors 110 comprises a combination of signal patterns, which makes it impossible to determine the target signal pattern 136 from the target active component 102. This, in turn, makes it impossible to evaluate the performance of the individual target active component 102 using prior LVP technology.

FIG. 1 further shows example optical testing setup(s) 100 as including computing device(s) 142. The computing device(s) 142 may include one or more of a desktop computer, laptop, tablet, smartphone, server(s), oscilloscope, amplifier, or other computing system that can execute and/or provide one or more functionalities attributed to the computing device 142 in the present disclosure. In some embodiments, individual sensors of the one or more sensors 110 may be separate from the computing device(s) 142, be a component element of one of the computing device(s) 142, or a combination thereof. The one or more sensors 110 and/or the computing device(s) 142 generate an analog signal from the portion of reflected energy 126 that is incident upon and/or detected by the one or more sensors 110.

FIG. 1 further includes A schematic diagram illustrating computing architecture 144 of an example computing device 142 configured to determine the performance of a target active component 102 of a device under test (DUT) 104. For instance, FIG. 1 illustrates additional details of hardware and software components that can be used to implement the techniques described in the present disclosure. In the example computing architecture 144, the computing device 142 includes one or more processors 144 and memory 146 communicatively coupled to the one or more processors 144.

The example computing architecture 144 can include a signal recovery module 148, a component performance module 150, and an output module 152 stored in the memory 146. As used herein, the term “module” is intended to represent example divisions of executable instructions for purposes of discussion and is not intended to represent any type of requirement or required method, manner or organization. Accordingly, while various “modules” are described, their functionality and/or similar functionality could be arranged differently (e.g., combined into a fewer number of modules, broken into a larger number of modules, etc.). Further, while certain functions and modules are described herein as being implemented by software and/or firmware executable on a processor, in other instances, any or all of modules can be implemented in whole or in part by hardware (e.g., a specialized processing unit, etc.) to execute the described functions. In various implementations, the modules described herein in association with the example computing architecture 144 can be executed across multiple devices.

The signal recovery module 148 can be executable by the processors 144 to determine an estimated target signal that corresponds to an estimated component of the amalgamation of multiple different signal patterns 140 that is attributable to the target reflected energy 128 from the target active component 102. For example, the signal recovery module 148 can generate a decomposition relationship that the signal recovery module 148 can use to generate the estimated target signal from the amalgamation of multiple different signal patterns 140 detected by the one or more sensors. According to the present disclosure, the decomposition relationship may correspond to a decomposition formula, an unmixing matrix, a table, or other type of data structure/relationship that describes relationships between the individual signal patterns of the amalgamation of multiple different signal patterns.

In some embodiments, the decomposition relationship may include component functions that describe the relationships between an amalgamation of multiple different signal patterns 140 detected by the one or more sensors, and the individual signal patterns of reflected energy that are component elements of the amalgamation 140. In this way, the decomposition relationship can be utilized to estimate individual component signal patterns of the amalgamation of multiple different signal patterns 140. For example, the signal recovery module 148 may use at least a portion of the decomposition relationship that corresponds to the target active component 102 to estimate the portion of the amalgamation of multiple different signal patterns 140 that is attributable to the target signal pattern 136. Alternatively, or in addition, the amalgamation of multiple different signal patterns 140 is a weighted mixture of independent signal patterns from separate active components of the DUT 104, the decomposition relationship may be configured such that when it is multiplied by the amalgamation 140, the result includes one or more individual component signal patterns of the amalgamation.

In some embodiments, the signal recovery module 148 is executable to determine a plurality of estimated signals that individually correspond to individual component signal patterns of the amalgamation of multiple different signal patterns 140. For example, based on an unmixing matrix, the signal recovery module 148 may be configured to determine an estimated target signal and an estimated additional signal, where the estimated target signal corresponds to an estimated component of the amalgamation of multiple different signal patterns 140 that is attributable to the target reflected energy 128 from the additional active component 102 and the estimated additional signal corresponds to an estimated component of the amalgamation of multiple different signal patterns 140 that is attributable to the additional reflected energy 130 from the additional active component 106. The estimated target signal can have one or more of a different phase as the estimated additional signal, the same phase as the estimated signal, a different amplitude as the estimated additional signal, the same phase as the estimated signal, a different frequency as the estimated additional signal, the same phase as the estimated signal, a different duty cycle as the estimated additional signal, and the same phase as the estimated signal.

The recovery module 148 may generate the decomposition relationship based on a plurality of amalgamations of multiple different signal patterns 140 detected by an example optical testing setup 100. For example, the recovery module 148 may generate the decomposition relationship based on first reflected energy that is detected by the one or more sensors 110 while the laser source 108 illuminates a first region of the DUT 120, and second reflected energy that is detected by the one or more sensors 110 while the laser source 108 illuminates a second region of the DUT 120. Alternatively, or in addition, the recovery module 148 may generate the decomposition relationship based on first reflected energy that is detected by the one or more sensors 110 over a first time period, and second reflected energy that is detected by the one or more sensors 110 over a second time period.

In some embodiments, the recovery module 148 may at least partly generate the decomposition relationship by applying a blind source separation (BSS) algorithm, such as independent component analysis (ICA), and/or ICA with reference to the plurality of amalgamations of multiple different signal patterns 140 detected by an example optical testing setup 100. The algorithm may further be a supervised or unsupervised machine learning algorithm. For example, the recovery module 148 can apply an unsupervised machine learning algorithm to generate a decomposition formula. The algorithm applied by the recovery module 148 may perform an ICA with reference on the plurality of amalgamations of multiple different signal patterns 140 detected by an example optical testing setup 100. In such embodiments, the reference signal(s) used by the recovery module 148 may include, but are not limited to, one or more of a synthetic signal simulated to have one or more features similar to the target signal (i.e., amplitude, frequency, phase, duty cycle, etc.), a synthetic signal simulated to correspond to an expected reflected signal from the target signal, a synthetic clock signal, or a combination thereof.

In some embodiments, one or more of generating the estimated analog signal from the portion of reflected energy 126 that is incident upon and/or detected by the one or more sensors 110, generating the decomposition relationship, and/or determining one or more estimated signal patterns may include amplifying the signal detected by the one or more sensors 110, applying a synchronous trigger to the analog signal, and/or determining component portions of the analog signal. For example, the recovery module 148 may be executable to split the analog signal into an AC component and a DC component.

The component performance module 150 can be executable by the processors 144 to determine performance of the target active component 102 based on the estimated target signal. For example, the component performance module may be configured to determine whether the signal pattern of the estimated target signal corresponds to the signal pattern that the target active component 102 would be expected to reflect if the target active component 102 was performing properly. This may involve the component performance module 150 determining whether one or more portions of the estimated target signal exhibit one or more characteristics (e.g., amplitude, periodicity, signal pattern, signal modulation, frequency, phase, etc.) that correspond to characteristics that would be expected if the target active component 102 was performing properly. For example, the component performance module 150 may determine that the target active component 102 is not performing properly because the signal modulation of one or more portions of the estimated target signal are different from an expected signal modulation. In some embodiments, the component performance module 150 can be executable may make such a determination based on a mapping (e.g., lookup table) stored on memory(s) 146 that indicates relationships between proper performance conditions (e.g., properly performing, improperly performing, etc.) of the target active component 102 and particular characteristics (e.g., an amplitude, an amplitude range, a periodicity, a signal pattern, a signal modulation, a frequency, a frequency range, a phase, etc.).

Alternatively, or in addition, the component performance module 150 may be executable to determine performance of the target active component 102 by comparing the estimated target signal to an expected reflected signal from the target active component 102. For example, the component performance module 150 may determine that the target active component 102 is performing properly based on a modulation and/or other characteristics of the estimated target signal being within a threshold level of similarity with an expected modulation for an expected reflected signal from the target active component. In some embodiments, the example computing architecture 144 optionally includes an expected signal module 154 that is executable to determine expected reflected signals. The expected signal module 154 can be configured to determine individual expected reflected signals for each of the target active component 102, the additional active component 106, and/or the other active component(s) 116.

In some embodiments, the example computing architecture 144 may further include an output module 152 executable to cause the processor(s) 144 to present the performance of one or more active components of the DUT 104, and/or cause an action to be performed based on the performance. Presenting the performance can include generating a health diagnostic report for the target active component 102, the region of the DUT 120, the DUT, or a combination thereof. The health diagnostic report may include a health score for each active component (e.g., numerical score, classification, percentage, color code, binary score, etc.) that indicates a level and/or state of performance for the corresponding active component. For example, the health score for the target active component 102 may be “performing as expected” based on a similarity between the estimated target signal and the expected target signal for the target active component 102 being within a threshold value.

Alternatively, or in addition, the output module 152 can be executable to cause the processors to generate and/or display a composite graph that includes both the estimated target signal and the expected target signal for the target active component 102. In some embodiments, the output module 152 can generate an image that includes a mapping of the active components of the DUT 104, and which further includes an overlay of graphics and/or health scores that indicate the performance of individual active components. For example, as part of a debugging process, the output module 152 may generate a mapping that has a visual indicator (e.g., icon, highlighted area, etc.) that indicates an active component that is causing a failure of the DUT 104 (i.e., that is not performing properly).

As further illustrated in FIG. 1, the computing architecture 144 may optionally include a display 156 and/or amplifier 158. The processor(s) may be executable to cause the display 156 to present one or more outputs generated by the output module 152. The amplifier 158 can be used to amplify the information detected by the one or more sensors 110, and/or a portion thereof (e.g., the AC portion of the detected information).

Those skilled in the art will appreciate that the computing architecture 144 is merely illustrative and is not intended to limit the scope of the present disclosure. In particular, the computing system and devices may include any combination of hardware or software that can perform the indicated functions, including computers, network devices, internet appliances, PDAs, wireless phones, oscilloscopes, amplifiers, etc. The computing architecture 144 may also be connected to other devices that are not illustrated, or instead may operate as a stand-alone system. In addition, the functionality provided by the illustrated components may in some implementations be combined in fewer components or distributed in additional components. Similarly, in some implementations, the functionality of some of the illustrated components may not be provided and/or other additional functionality may be available.

The one or more processors 146 may be configured to execute instructions, applications, or programs stored in the memories 148. In some examples, the one or more processors 146 may include hardware processors that include, without limitation, a hardware central processing unit (CPU), a graphics processing unit (GPU), and so on. While in many instances the techniques are described herein as being performed by the one or more processors 146, in some instances the techniques may be implemented by one or more hardware logic components, such as a field programmable gate array (FPGA), a complex programmable logic device (CPLD), an application specific integrated circuit (ASIC), a system-on-chip (SoC), or a combination thereof.

The memories 148 are examples of computer-readable media. Computer-readable media may include two types of computer-readable media, namely computer storage media and communication media. Computer storage media may include volatile and non-volatile, removable, and non-removable media implemented in any method or technology for storage of information, such as computer readable instructions, data structures, program modules, or other data. Computer storage media includes, but is not limited to, random access memory (RAM), read-only memory (ROM), erasable programmable read only memory (EEPROM), flash memory or other memory technology, compact disc read-only memory (CD-ROM), digital versatile disk (DVD), or other optical storage, magnetic cassettes, magnetic tape, magnetic disk storage or other magnetic storage devices, or any other non-transmission medium that may be used to store the desired information and which may be accessed by a computing device. In general, computer storage media may include computer•executable instructions that, when executed by one or more processing units, cause various functions and/or operations described herein to be performed. In contrast, communication media embodies computer-readable instructions, data structures, program modules, or other data in a modulated data signal, such as a carrier wave, or other transmission mechanism. As defined herein, computer storage media does not include communication media.

Those skilled in the art will also appreciate that, while various items are illustrated as being stored in memory or storage while being used, these items or portions of them may be transferred between memory and other storage devices for purposes of memory management and data integrity. Alternatively, in other implementations, some or all of the software components may execute in memory on another device and communicate with the illustrated computing architecture 144. Some or all of the system components or data structures may also be stored (e.g., as instructions or structured data) on a non-transitory, computer accessible medium or a portable article to be read by an appropriate drive, various examples of which are described above. In some implementations, instructions stored on a computer-accessible medium separate from the computing architecture 144 may be transmitted to the computing architecture 144 via transmission media or signals such as electrical, electromagnetic, or digital signals, conveyed via a communication medium such as a wireless link. Various implementations may further include receiving, sending or storing instructions and/or data implemented in accordance with the foregoing description upon a computer-accessible medium.

The architectures, systems, and individual elements described herein may include many other logical, programmatic, and physical components, of which those shown in the accompanying figures are merely examples that are related to the discussion herein.

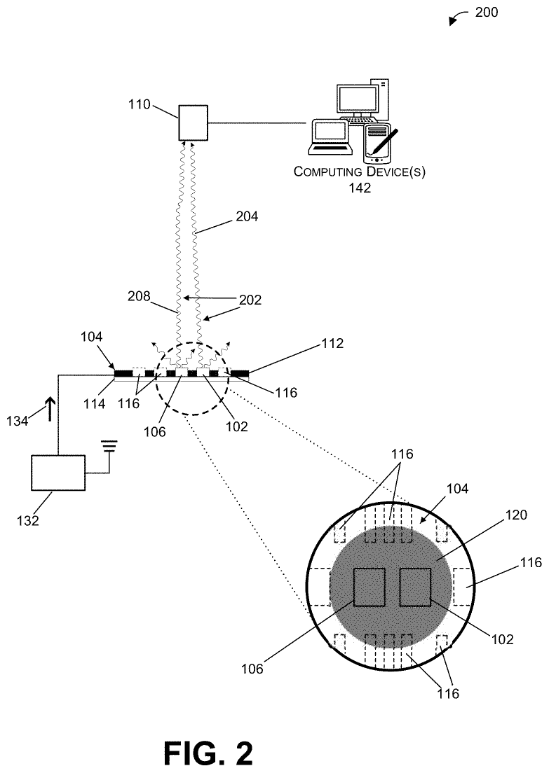

FIG. 2 is an illustration of example optical testing setup(s) 200 for determining the performance of a target active component 102 of a device under test (DUT) 104. Specifically, FIG. 2 is an illustration of example optical testing setup(s) 200 for determining the performance of a target active component 102 of a device under test (DUT) 104 using time resolved emission testing.

In time resolved emission testing, an electrical signal source 132 is configured to provide an electric signal 134 to the DUT 104. The electric signal 134 is a stimulus pattern that is repetitively applied to the DUT 104, and which causes one or more of the target active component 102, the additional active component 106, and/or one or more other active component(s) 116 to be switched between an on state and an off state. As individual active components are switched between an on and off state they emit an increased amount of emitted energy 202 (e.g., photons). In this way, the emitted energy 202 produced by each active component is modulated over time in correspondence with the pattern that the corresponding active component is switched between an on state and an off state. For example, FIG. 2 illustrates that the target emitted energy 204 produced by the target active component 102 as being modulated according to a target signal pattern and the additional emitted energy 208 produced by the additional active component 106 as being modulated according to an additional signal pattern.

FIG. 2 further shows example optical testing setup(s) 200 including one or more sensors 110 configured to detect emitted energy 202. The emitted energy 202 detected by the sensors 110 can be used to construct a photon histogram that indicates the number of photons detected over time. Over time, the photon histograms indicate a waveform emission signal from the active components (i.e., the target active component 102, the additional active component 106, and/or one or more other active component(s) 116) that is resultant of the electrical signal source 132. As shown in FIG. 2, the emitted energy 202 may include target emitted energy 204 that corresponds to energy that is emitted from the target active component 102, and additional emitted energy 208 that corresponds to energy that is emitted from the additional active component 106. For example, an optical testing setup 100 may include a photodetector that is configured to detect the emitted energy 202 from the target active component 102, the additional active component 106, and/or one or more other active component(s) 116. While FIG. 2 illustrates the sensors 110 as being positioned to detect emitted energy 202 that is emitted upward from the upper layer 112 of the DUT 104, in other embodiments the sensors 110 may be positioned to detect emitted energy 202 that is emitted downward from the active components and through the base layer 114.

Because present technology sensors are not able to differentiate between the target emitted energy 204, the additional emitted energy 208, and/or other emitted energy from the other active component(s) 116, the information output by the one or more sensors 110 comprises the amalgamation of multiple different signal patterns. For example, the one or more sensors 110 may detect the emitted energy 202 over time and generate a histogram that shows the signal pattern of the energy it detects. However, because the one or more sensors 110 are unable to differentiate the target emitted energy 204 from the additional emitted energy 208, the histogram of the energy detected by the one or more sensors 110 shows the amalgamation of multiple different signal patterns. This cross talk makes it impossible to determine the target signal pattern from the target active component 102. This, in turn, makes it impossible to evaluate the performance of the individual target active component 102 using prior time resolved emission testing.

However, example optical testing setup(s) 200 improves upon prior systems by allowing the target signal pattern to be determined from the amalgamation of multiple different signal patterns. Specifically, using the processes discussed above with regard to FIG. 1, computing devices 142 are configured to receive the amalgamation of multiple different signal patterns from the one or more sensors 110, and generate a decomposition relationship that describes the relationships between the amalgamation of multiple different signal patterns detected by the sensor, and the individual signal patterns of reflected energy that are component elements of the amalgamation. According to the present disclosure, the decomposition relationship may correspond to a decomposition formula, an unmixing matrix, a table, or other type of data structure/relationship generated by the computing devices 142 to describe relationships between the individual signal patterns of the amalgamation of multiple different signal patterns.

In various embodiments, the computing device 142 may generate the decomposition relationship by applying a blind source separation (BSS) algorithm, such as an independent component analysis (ICA), or a machine learning algorithm, or a combination thereof to the amalgamation of multiple different signal patterns. For example, the computing device may apply an ICA with reference analysis on the amalgamation of multiple different signal patterns to generate the decomposition relationship. In such embodiments, the reference signal(s) may include, but are not limited to, one or more of a synthetic signal simulated to have one or more features similar to the target signal (i.e., amplitude, frequency, phase, duty cycle, etc.), a synthetic signal simulated to correspond to an expected reflected signal from the target signal, a synthetic clock signal, or a combination thereof.

As also discussed with regard to FIG. 1, the computing devices 142 are further configured to determine an estimated emitted target signal that corresponds to the portion of the amalgamation of multiple different signal patterns that is the target emitted energy 204. That is, the estimated emitted target signal has characteristics (e.g., amplitude, modulation pattern, signal pattern, frequency, periodicity, phase, etc.) that are estimated by the computing device 142 to be the same as the target emitted energy 204 emitted by the active component 102 over time.

The computing devices 142 then determine a performance of the target active component 102 based on the estimated target signal. For example, the computing device 142 may determine whether the signal pattern of the estimated target signal does not match the signal pattern that the target active component 102 would be expected to reflect if the target active component 102 was performing properly (i.e., one or more portions of the estimated target signal exhibits one or more characteristics that would not be expected if the target active component 102 was performing properly).

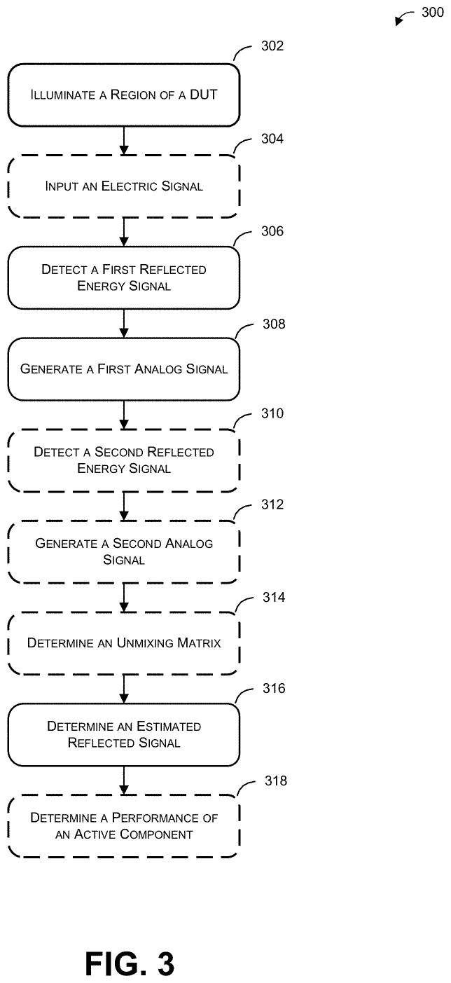

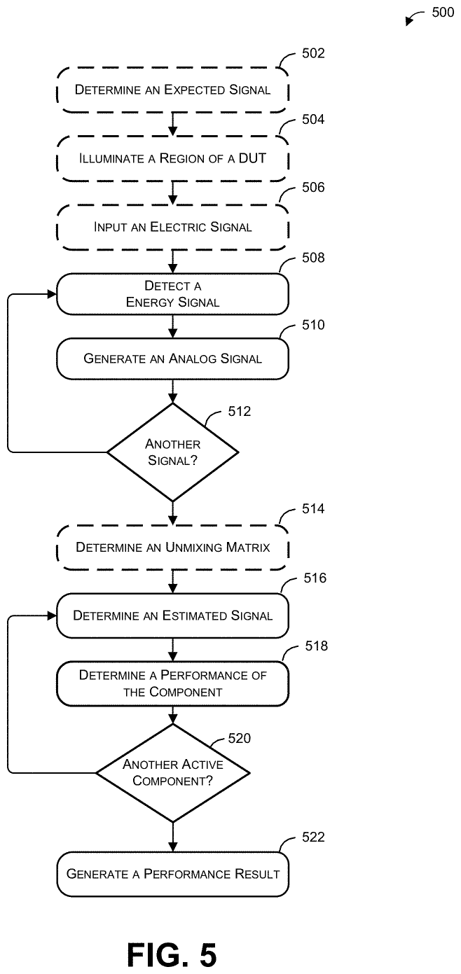

FIGS. 3 and 5 are flow diagrams of illustrative processes illustrated as a collection of blocks in a logical flow graph, which represent a sequence of operations that can be implemented in hardware, software, or a combination thereof. In the context of software, the blocks represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the processes.

FIG. 3 is a flow diagram of an illustrative process 300 for determining the performance of a target active component of a device under test (DUT). The process 300 may be implemented in an example optical testing setup 100 and by the computing architecture 144 described above, or in other environments and architectures.

At 302, a region of a DUT is illuminated. In some embodiments, an energy source (e.g., a laser source) that is configured is used to direct a focused energy beam onto the DUT so that the region of the DUT is illuminated. The energy source is configured to direct a focused energy beam to pass through a substrate base layer of the DUT, and to strike and/or illuminate one or more active components of the DUT. One or more focusing structures (e.g., one or more lenses) can be used to cause the focused energy beam to illuminate the region of the DUT. In contemporary high-performance circuits where the diameter of individual active components may be less than or equal to 10 nm, the illuminated region of the DUT may include 2, 4, 10, 20, 100, 200, or more individual active components. For example, a laser source can be used to cause an energy beam to pass through a silicon substrate of an integrated circuit under test so that energy source strikes and/or illuminates a target active component and four additional active components.

At 304, an electrical signal is optionally input to the DUT. For example, an electrical signal source can be configured to provide an electric signal to the DUT that causes individual component active components of the DUT to be switched between an on state and an off state. These changes in state, in turn, cause the voltage of each of the individual active components to be modulated over time. As the voltage of each individual active components is modulated over time, the reflectivity of individual active components and/or the refraction index of a portion of the substrate base layer proximate to an individual active component in correspondence with the voltage of the corresponding active component. This causes the portion of the focused energy beam that is reflected by individual active components to be modulated in correspondence with the individual active component's voltage.

At 306, first reflected energy is detected. At least a portion of the focused energy beam that is reflected by the active components within the illuminated region of the DUT is incident upon and/or is detected by a sensor (e.g., a photodetector). Then, at 308, a first analog signal is generated based on the portion of the energy that incident upon and/or is detected by the sensor over time. Because present technology sensors are unable to differentiate between the portions of the incident/detected energy that is attributable to individual active components, the first analog signal can comprise energy from multiple active components illuminated by the focused energy beam. As each active component reflects energy according to a signal pattern that corresponds to the modulation of the voltage of the active component, the first analog signal is an amalgamation of multiple different signal patterns. In other words, when there are more than one active components within the illuminated region of the DUT, the first analog signal is a combination of the individual signal patterns from each of the active components within the illuminated region of the DUT. This makes it impossible to evaluate individual signal patterns reflected by individual active components, which hinders the ability to evaluate the performance of the individual active components.

At 310, second reflected energy optionally is detected. The second reflected energy may be the portion of the focused energy beam that is reflected by the active components within the illuminated region of the DUT is incident upon and/or is detected by a sensor, where a different region of the DUT is illuminated by the focused energy beam than when the first reflected energy was detected, the sensor is in a different position than where the first reflected energy was detected, the reflected energy is detected over a different time period, or a combination thereof. Alternatively, or in addition, the second reflected energy may be detected by an additional sensor that is different from the sensor that detected the first reflected energy. At 312, a second analog signal is optionally generated. The second analog signal is generated based on the portion of the energy that incident upon and/or is detected by the sensor over time.

At 314, a decomposition relationship is optionally determined from the first analog signal and/or the second analog signal. Additionally, in some embodiments, the decomposition relationship may be determined from more analog signals than just the first analog signal and/or the second analog signal. That is, according to the present disclosure the decomposition relationship can be determined based on any number of analog signals that are generated from reflected signals detected by the one or more sensors over different periods of time, detector locations, regions of interest, or combinations thereof.

The decomposition relationship may describe the relationships between the amalgamation of multiple different signal patterns detected by the sensor, and the individual signal patterns of reflected energy that are component elements of the amalgamation. In this way, the decomposition relationship can be utilized to estimate individual component signal patterns from the first analog signal and/or second analog signal. According to the present disclosure, the decomposition relationship may correspond to a decomposition formula, an unmixing matrix, a table, or other type of data structure/relationship generated by the computing devices to describe relationships between the individual signal patterns of the amalgamation of multiple different signal patterns. The decomposition relationship may be generated by applying a blind source separation (BSS) algorithm to the first analog signal and/or second analog signal. The algorithm may further be an machine learning algorithm.

At 316, an estimated reflected signal is determined. The estimated reflected signal is the portion of the first analog signal and/or the second analog signal that is determined to correspond to the portion of the detected reflected energy that was reflected by a particular active component. In this way, the estimated reflected signal has characteristics (e.g., amplitude, modulation pattern, signal pattern, frequency, periodicity, phase, etc.) that are estimated to be the same as the reflected energy reflected by the particular active component over time. The estimated reflected signal is determined based at least in part on one or more of the decomposition relationship, the first analog signal, and the second analog signal.

At 318, a performance of the active component is determined. For example, the performance of the active component that corresponds to the estimated reflected signal may be determined. This may involve determining whether one or more portions of the estimated signal exhibit one or more characteristics (e.g., amplitude, periodicity, signal pattern, signal modulation, frequency, phase, etc.) that correspond to characteristics that would be expected if the active component was performing properly. For example, the active component may be determined to not be performing properly because the signal modulation of one or more portions of the estimated signal is different from an expected signal modulation. The determination of performance may be based on a mapping (e.g., a lookup table) that indicates relationships between proper performance conditions (e.g., properly performing, improperly performing, etc.) of the active component and particular characteristics. The determination of performance may be based on a comparison between the estimated signal and an expected reflected signal from the active component.

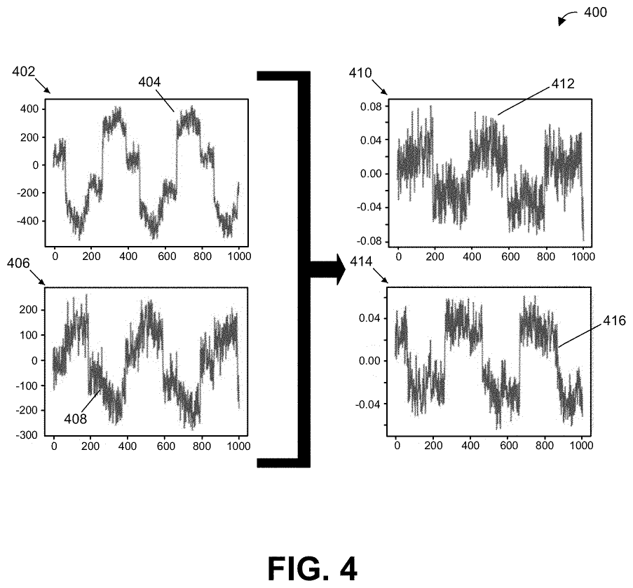

FIG. 4 is a diagram that illustrates a sample process 400 for determining the estimated reflected signals from a plurality of analog signals. FIG. 4 shows graph 402 that depicts a first analog signal 404, and graph 406 that depicts a second analog signal 408. Each of first analog signal 404 and the second analog signal 408 are an amalgamation of a plurality of reflected energy signals from individual active components. The first analog signal 404 can correspond reflected energy that is detected at a first sensor location, over a first time period, for a first illuminated region of the DUT, or a combination thereof. Similarly, the second analog signal 408 can correspond reflected energy that is detected at a second sensor location, over a second time period, for a second illuminated region of the DUT, or a combination thereof.

FIG. 4 further shows graph 410 that depicts a first estimated reflected signal 412, and graph 414 that depicts a second estimated reflected signal 416 that are each generated according to the present disclosure. For example, each of the first estimated reflected signal 412 and the second estimated reflected signal 416 may be determined from the first analog signal 404 and the second analog signal 408, and using one or more algorithms, such as BSS, ICA, ICA with reference, etc. Each of the first estimated reflected signal 412 and the second estimated reflected signal 416 corresponds to an estimated portion of the first analog signal 404 and the second analog signal 408 that is attributable to the energy reflected by a single active component of the DUT.

FIG. 5 is a flow diagram of an illustrative process 500 for determining the performance of one or more active components of a device under test (DUT). The process 500 may be implemented in an example optical testing setup 100 and by the computing architecture 144 described above, or in other environments and architectures.

At 502, an expected signal is optionally determined. For example, as part of the process of debugging a DUT, an expected signal may be determined that has characteristics (e.g., amplitude, modulation pattern, signal pattern, frequency, periodicity, phase, etc.) that energy reflected from a particular active component of the DUT is expected to exhibit. In some embodiments, an expected signal is determined for each of the active components of the DUT that are to be debugged.

At 504, a region of a DUT is illuminated. In some embodiments, a light source (e.g., a laser source, a LED, a SLED, etc.) that is configured is used to direct a focused energy beam onto the DUT so that the region of the DUT is illuminated. The energy source is configured to direct a focused energy beam to pass through a substrate base layer of the DUT, and to strike and/or illuminate one or more active components of the DUT. One or more focusing structures (e.g., one or more lenses) can be used to cause the focused energy beam to illuminate the region of the DUT. In contemporary high-performance circuits where the diameter of individual active components may be less than or equal to 10 nm (e.g., 5 nm, 10 nm, etc.), the illuminated region of the DUT may include 2, 4, 10, 20, 100, 200, or more individual active components. For example, a laser source can be used to cause an energy beam to pass through a silicon substrate of an integrated circuit under test so that energy source strikes and/or illuminates a target active component and four additional active components.

At 506, an electrical signal is optionally input to the DUT. For example, an electrical signal source can be configured to provide an electric signal to the DUT that causes individual component active components of the DUT to be switched between an on state and an off state. These changes in state, in turn, cause the voltage of each of the individual active components to be modulated over time. As the voltage of each individual active components is modulated over time, the reflectivity of individual active components and/or the refraction index of a portion of the substrate base layer proximate to an individual active component in correspondence with the voltage of the corresponding active component. This causes the portion of the focused energy beam that is reflected by individual active components to be modulated in correspondence with the individual active component's voltage.

At 508, energy is detected. For example, at least a portion of the focused energy beam that is reflected by the active components within the illuminated region of the DUT is incident upon and/or is detected by a sensor (e.g., a photodetector). Alternatively, the energy detected by the sensor may be energy emitted by the active components as part of time resolved emission testing, such as described above in association with FIG. 2.

At 510, an analog signal is generated based on the portion of the energy that incident upon and/or is detected by the sensor over time. Because present technology sensors are unable to differentiate between the portions of the incident/detected energy that is attributable to individual active components, the analog signal can comprise energy from multiple active components illuminated by the focused energy beam. As each active component reflects and/or emits energy according to a signal pattern that corresponds to the modulation of the voltage of the active component, the analog signal is an amalgamation of multiple different signal patterns. In other words, when there are more than one active components within the illuminated region of the DUT, the analog signal is a combination of the individual signal patterns from each of the active components within the illuminated region of the DUT. This makes it impossible to evaluate individual signal patterns reflected and/or emitted by individual active components, which hinders the ability to evaluate the performance of the individual active components.

At 512, it is determined whether there is another signal to be detected. In some embodiments, the number of signals that are to be detected is based on a number of active components that are illuminated by the energy source. Alternatively, or in addition, the number of signals that are to be detected can be based on the number of signals in the number of independent signals in the analog signal. If it is determined that there is another signal to be detected, the process 500 returns to 508, and additional energy is detected. The additional energy may be the portion of the focused energy beam that is reflected by the active components within the illuminated region of the DUT is incident upon and/or is detected by a sensor, where a different region of the DUT is illuminated by the focused energy beam than when the initial energy was detected, the sensor is in a different position than where the initial energy was detected, over a different time period, or a combination thereof. Alternatively, or in addition, the additional energy may be detected by an additional sensor that is different from the sensor that detected the initial energy. In an alternative embodiment, the additional energy may be additional energy emitted by the active components as part of time resolved emission testing. The additional energy emitted may be detected while the sensor is detecting energy from a different position than where the initial energy was detected, over a different time period, or a combination thereof.

If it is determined that there is not another signal to be detected, the process 500 continues at 514, where a decomposition relationship is optionally determined from the analog signal and/or the additional analog signals. The decomposition relationship may describe the relationships between the amalgamation of multiple different signal patterns detected by the sensor, and the individual signal patterns of reflected and/or emitted energy that are component elements of the amalgamation. In this way, the decomposition relationship can be utilized to estimate individual component signal patterns from the analog signal and/or additional analog signals. The decomposition relationship may be generated by applying a blind source separation (BSS) algorithm, for example, independent component analysis (ICA) techniques and/or ICA with reference to the analog signal and/or additional analog signal. The algorithm may further be an machine learning algorithm. For example, ICA techniques and/or ICA with reference may be applied on the analog signal and/or additional analog signals to generate an unmixing matrix. In such embodiments, the reference signal(s) may include, but are not limited to, one or more of a synthetic signal simulated to have one or more features similar to a target signal (i.e., amplitude, frequency, phase, duty cycle, etc.), a synthetic signal simulated to correspond to an expected signal from the target signal, a synthetic clock signal, or a combination thereof.

At 516, an estimated signal is determined. The estimated signal is the portion of the analog signal and/or the additional analog signals that are determined to correspond to the portion of the detected energy that was by a particular active component. In this way, the estimated signal has characteristics (e.g., amplitude, modulation pattern, signal pattern, frequency, periodicity, phase, etc.) that are estimated to be the same as the energy reflected and/or emitted by the particular active component over time. The estimated signal is determined based at least in part on one or more of the decomposition relationship, the analog signal, and the additional analog signals.

At 518, a performance of the active component is determined. For example, the performance of the active component that corresponds to the estimated signal may be determined. This may involve determining whether one or more portions of the estimated signal exhibit one or more characteristics (e.g., amplitude, periodicity, signal pattern, signal modulation, frequency, phase, etc.) that correspond to characteristics that would be expected if the active component was performing properly. For example, the active component may be determined to not be performing properly because the signal modulation of one or more portions of the estimated signal is different from an expected signal modulation. The determination of performance may be based on a mapping (e.g., a lookup table) that indicates relationships between proper performance conditions (e.g., properly performing, improperly performing, etc.) of the active component 102 and particular characteristics. The determination of performance may be based on a comparison between the estimated signal and the expected signal determined at 502.

At 520, it is determined whether there is another active component that is to be evaluated. If there is another active component to be evaluated, process 500 returns to 516 and an additional estimated signal is determined. If it is determined that there is not another active component to be evaluated, the process 500 continues at 522, and a performance result is generated.

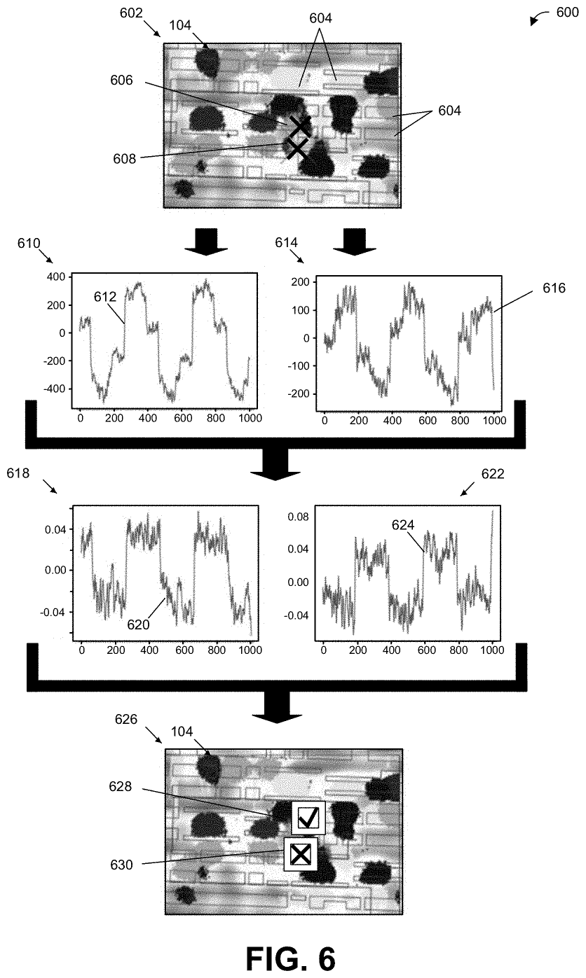

FIG. 6 is a diagram that illustrates a sample process 600 for determining the performance of one or more active components of a DUT. FIG. 4 shows an image 602 that illustrates a mapping of the DUT 104 described in association with FIGS. 1 and 2. The DUT 104 is shown as having a plurality of active components 604. Image 602 further shows a first signal location 606 and a second signal location 608. Each of the first signal location 606 and the second signal location 608 correspond to a location at which a reflected energy signal was detected by one or more sensors of an example optical testing setups 100 and 200. The first signal location 606 can correspond to a location in which reflected energy is detected from a first region of the DUT illuminated by a focused laser beam, and the second signal location 608 can correspond to a location in which reflected energy is detected from a second region of the DUT by the focused laser beam. Each of the first region of the DUT and the second region of the DUT may include a first active component and a second active component.

FIG. 6 further shows graph 610 that depicts a first analog signal 612 detected at the first signal location 606, and graph 614 that depicts a second analog signal 616 detected at the second signal location 608. The first analog signal 612 may correspond to a portion of the reflected energy from the first region of the DUT that was detected by one or more sensors of the example optical testing setups 100 and/or 200. Similarly, the second analog signal 616 may correspond to a portion of the reflected energy from the first region of the DUT that was detected by one or more sensors of the example optical testing setups 100 and/or 200.

FIG. 6 additionally shows graph 618 that depicts a first estimated reflected signal 620, and graph 622 that depicts a second estimated reflected signal 624 that are each generated according to the present disclosure. For example, each of the first estimated reflected signal 620 and the second estimated reflected signal 624 may be determined from the first analog signal 612 and the second analog signal 616, and using one or more algorithms, such as BSS, ICA, ICA with reference, etc. Each of the first estimated reflected signal 620 and the second estimated reflected signal 624 corresponds to an estimated portion of the first analog signal 612 and the second analog signal 616 that is attributable to the energy reflected by a single active component of the DUT. For example, the first estimated reflected signal 620 may correspond to the portion of the first analog signal 612 and the second analog signal 616 that is attributable to energy reflected by the first active component, while the second estimated reflected signal 624 may correspond to the portion of the first analog signal 612 and the second analog signal 616 that is attributable to energy reflected by the second active component.

Also illustrated in FIG. 6 is an example output 626 according to the present disclosure. Output 626 shows a mapping of the DUT 104 that includes a performance overlay. Specifically, output 626 includes a positive performance overlay 628, and a negative performance overlay 630. For example, the negative performance overlay 630 may be included within output 626 based on a determination that the first estimated signal 620 indicates that the first active component is not performing properly.

Examples of inventive subject matter according to the present disclosure are described in the following enumerated paragraphs.

A1. A method for optically determining performance of active components of a device under test (DUT), the method comprising:

illuminating a portion of the DUT with a focused laser beam, wherein the focused laser beam illuminates the portion of the DUT that includes a target active component and an additional active component;

detecting, by one or more sensors, first reflected energy from the DUT, wherein the first reflected energy comprises a first portion of target reflected energy from the target active component, and a first portion of additional reflected energy from the additional active component;

generating, by a processor, a first analog signal that corresponds to the first reflected energy detected by the one or more sensors;

detecting, by the one or more sensors, second reflected energy from the DUT, wherein the second reflected energy comprises a second portion of the target reflected energy from the target active component, and a second portion of the additional reflected energy from the additional active component;

generating, by the processor, a second analog signal that corresponds to the second reflected energy detected by the one or more sensors;

determining, by the processor and based on the first analog signal and the second analog signal, an estimated target signal that corresponds to an estimated component of the first analog signal and the second analog signal that is attributable to the target reflected energy from the target active component, wherein determining the estimated target signal comprises:

applying an algorithm to the first analog signal and the second analog signal to generate a decomposition relationship; and

generating, based on the decomposition relationship, the estimated target signal from at least one of the first analog signal and the second analog signal; and

determining a performance of the target active component of the DUT based on the estimated target signal.

A1.1. The method of paragraph A1, wherein the decomposition relationship is one of a decomposition formula, an unmixing matrix, a table, or other type of data structure/relationship generated by the computing devices to describe relationships between the individual signal patterns of the amalgamation of multiple different signal patterns.

A2. The method of any of paragraphs A1-A1.1, wherein the algorithm is a blind source separation (BSS) algorithm.

A3. The method of any of paragraphs A1-A2, wherein the algorithm is a machine learning algorithm.

A3.1. The method of paragraph A3, wherein the algorithm is a supervised machine learning algorithm.

A3.2. The method of paragraph A3, wherein the algorithm is an unsupervised machine learning algorithm.

A4. The method of any of paragraphs A1-A3, wherein the algorithm performs an independent component analysis (ICA) for the reflected signal.

A4.1. The method of paragraph A4, wherein the algorithm performs an ICA with reference for the reflected signal.

A4.1.1. The method of paragraph A4.1, wherein the reference is a synthetic signal simulated to have one or more features similar to the target signal.

A4.1.1.1. The method of paragraph A4.1.1, wherein the one or more features comprise one or more of amplitude, frequency, phase, and duty cycle.

A4.1.2. The method of any of paragraphs A4.1-A4.1.1.1, wherein the reference is a synthetic signal simulated to correspond to an expected reflected signal from the target signal.

A4.1.3. The method of any of paragraphs A4.1-A4.1.1.1, wherein the reference is a synthetic clock signal.

A5. The method of any of paragraphs A1-A4.1.3, wherein the first analog signal corresponds to a weighted mixture of energy detected from the target reflected energy from the target active component, and the additional reflected energy from the additional active component.

A6. The method of any of paragraphs A1-A5, wherein the first reflected energy is detected by the one or more sensors at a first location, and wherein the second reflected energy is detected by the one or more sensors at a second location different from the first location.

A7. The method of any of paragraphs A1-A6, wherein the first reflected energy is detected by the one or more sensors during a first time period, and wherein the second reflected energy is detected by the one or more sensors during a first time period that is different from the first time period.

A8. The method of any of paragraphs A1-A7, further comprising generating, by the processor and based on the decomposition relationship, an estimated additional signal from the first reflected signal and the second reflected signal, wherein the estimated additional signal corresponds to an estimated component of the first analog signal and the second analog signal that is attributable to the additional reflected energy from the additional active component.

A8.1. The method of paragraph A8, wherein the estimated target signal has at least one of: a different phase as the estimated additional signal; a different amplitude as the estimated additional signal; a different frequency as the estimated additional signal; and a different duty cycle as the estimated additional signal.

A9. The method of any of paragraphs A1-A8.1, further comprising applying an electric signal to the DUT.

A9.1. The method of paragraph A9, wherein the electric signal causes the voltage on the target active component to be modulated over time.

A9.2. The method of any of paragraphs A9-A9.1, wherein the electric signal causes the target active component to be switched between an on state and an off state.

A9.3. The method of any of paragraphs A9-A9.2, wherein the electrical signal comprises a clock signal.

A9.4. The method of any of paragraphs A9-A9.3, wherein the reflectivity of the target active component changes in correspondence with the voltage of the target active component.

A9.5. The method of any of paragraphs A9-A9.3, wherein a change in the voltage of the target active component causes a corresponding change in the refraction index of a portion of the silicon substrate layer proximate to the DUT.

A10. The method of any of paragraphs A1-A9.5, wherein the target active component is a transistor.

All. The method of any of paragraphs A1-A9.5, wherein the target active component corresponds to a region of a transistor.

A11.1. The method of paragraph A11, wherein the region of the transistor corresponds to one of a p-drain, a p-gate, an n-drain, and/or an n-gate.

A12. The method of any of paragraphs A10-A11.1, wherein the transistor is located on a CMOS construction.

A13. The method of any of paragraphs A1-A12, wherein each of the first analog signal and the second analog signal comprises an AC component and a DC component.

A13.1. The method of paragraph A13, further comprising causing the AC component of at least one of the first analog signal and the second analog signal to be received by a digital scope.

A13.2. The method of any of paragraphs A13-A3.1, further comprising applying a synchronous trigger to the AC component of at least one of the first analog signal and the second analog signal.

A13.3. The method of any of paragraphs A13-A13.2, wherein applying the algorithm to the first analog signal and the second analog signal comprises applying the algorithm to the AC component of the at least one of the first analog signal and the second analog signal.

A14. The method of any of paragraphs A1-A13.3, wherein the portion of the DUT illuminated by the focused laser beam includes a plurality of additional active components.

A14.1. The method of paragraph A14, wherein each additional active component of the plurality of additional active components is a transistor.

A14.2. The method of any of paragraphs A14-A14.1, wherein each of the first reflected energy and the second reflected energy further comprises an individual reflected energy from each additional active components of the plurality of additional active components.

A15. The method of any of paragraphs A1-A14.2, wherein the portion of the DUT illuminated by the focused laser beam further includes a further active component of the DUT.

A15.1. The method of paragraph A15, wherein the method further comprises detecting, by the one or more sensors, a third reflected energy from the DUT, wherein each of the first reflected energy, the second reflected energy and the third reflected energy comprises a portion of further reflected energy from the further active component.

A15.2. The method of any of paragraphs A15-A15.1, wherein the decomposition relationship is further determined based on the third analog signal.

A15.2.1. The method of paragraph A15.2, further comprising generating, by the processor and based on the decomposition relationship, an estimated further signal that corresponds to an estimated component of the first analog signal, the second analog signal, and/or the third analog signal that is attributable to the further reflected energy from the further active component.

A16. The method of any of paragraphs A1-A15.2.1, wherein determining the performance of the target active component of the DUT comprises comparing the estimated target signal to an expected reflected signal from the target active component.

A16.1. The method of paragraph A16, wherein determining the performance of the target active component of the DUT comprises determining that the target active component is performing properly based on a modulation of the estimated target signal being within a threshold level of similarity with an expected modulation for an expected reflected signal from the target active component.

A16.2. The method of paragraph A16, wherein determining the performance of the target active component of the DUT comprises determining that the target active component is not performing properly based on a modulation of the estimated target signal not being within a threshold level of similarity of an expected modulation for an expected reflected signal from the target active component.

A16.3. The method of any of paragraphs A16-A16.2, wherein determining the performance of the target active component of the DUT comprises isolating an electrical failure in the DUT based on the estimated target reflected signal.

A17. The method of any of paragraphs A1-A16.3, wherein the DUT comprises an upper layer and a lower layer, wherein the upper layer comprises at least the target active component and the additional active component, and the lower layer comprises a substrate base layer.

A17.1. The method of paragraph A17, wherein illuminating the portion of the DUT with the focused laser beam comprises causing the focused laser beam to pass through the silicon base layer and onto the target active component and the additional active component.

A18. The method of any of paragraphs A1-A17.1, wherein at least one of the target active component of the DUT and the additional active component of the DUT have a diameter equal to or less than 2 nm, 5 nm, and/or 10 nm.

A19. The method of any of paragraphs A1-A18, wherein the one or more sensors comprise a photodetector.

B1. A system for optically determining performance of components of a DUT, the system comprising:

the DUT, wherein the DUT comprises an upper layer and a lower layer, wherein the upper layer comprises at least a target active component and an additional active component of the DUT, and the lower layer comprises a silicon base layer;

a laser source configured to cause a focused laser beam to pass through the silicon base layer and illuminate a portion of the DUT that includes the target active component and the additional active component of the DUT;

one or more sensors configured to detect energy reflected from at least the target active component and the additional active component of the DUT;

one or more processors; and

a memory storing non-transitory computer readable instructions that, when executed by the one or more processors, cause the one or more processors to perform the method of any of paragraphs A1-A19.1.

B2. The system of paragraph B1, wherein the one or more sensors comprise a photodetector.

B3. The system of any of paragraphs B1-B2, further comprising a lens configured to focus the focused laser beam to illuminate the portion of the DUT.

B3.1. The system of paragraph B3, wherein the lens is a field immersion lens.

C1. Use of the system of any of paragraphs B1-B3.1 to perform the method of any of paragraphs A1-A19.1.

D1. A non-transitory computer readable media storing instructions that, when executed by a processor, causes the processor to initiate the performance of the method of any of paragraphs A1-A19.1.

E1. Use of the computer readable media of paragraph D1 to perform the method of any of paragraphs A1-A19.1.

What is claimed is:

1. A method for optically determining performance of active components of a device under test (DUT), the method comprising:
illuminating a portion of the DUT with a light source, wherein the light source illuminates the portion of the DUT that includes a target active component and an additional active component;
detecting, by one or more sensors, first energy from the DUT, wherein the first energy comprises a first portion of target energy received from the target active component, and a first portion of additional energy received from the additional active component;
generating, by a processor, a first analog signal that corresponds to the first energy detected by the one or more sensors;
detecting, by the one or more sensors, second energy received from the DUT, wherein the second energy comprises a second portion of the target energy received from the target active component, and a second portion of the additional energy from the additional active component;
generating, by the processor, a second analog signal that corresponds to the second energy detected by the one or more sensors;
determining, by the processor and based on the first analog signal and the second analog signal, an estimated target signal that corresponds to an estimated component of the first analog signal and the second analog signal that is attributable to energy received from the target active component; and
determining a performance of the target active component of the DUT based on the estimated target signal.

2. The method claim 1, wherein determining the estimated target signal comprises:
applying an algorithm to the first analog signal and the second analog signal to generate a decomposition relationship that defines a relationship between the target reflected energy and at least one of the first analog signal and the second analog signal; and
generating, based on the decomposition relationship, the estimated target signal from at least one of the first analog signal and the second analog signal.

3. The method claim 2, wherein the algorithm is a blind source separation (BSS) algorithm.

4. The method of claim 2, wherein the algorithm performs an independent component analysis (ICA).

5. The method of claim 2, wherein the algorithm performs an ICA with reference, and wherein the reference comprises a synthetic signal simulated to have one or more features similar to features expected for energy reflected by the target active component.

6. The method of claim 5, wherein the one or more features comprise one or more of amplitude, frequency, phase, and duty cycle.

7. The method of claim 2, wherein the algorithm performs an ICA with reference, and wherein the reference comprises a synthetic signal simulated to correspond to an expected reflected signal from the target active component.

8. The method of claim 2, further comprising generating, by the processor and based on the decomposition relationship, an estimated additional signal from the first analog signal and the second analog signal, wherein the estimated additional signal corresponds to an estimated component of the first analog signal and the second analog signal that is attributable to energy reflected from the additional active component.

9. The method of claim 8, wherein the estimated target signal has at least one of:
a different phase as the estimated additional signal; a different amplitude as the estimated additional signal; a different frequency as the estimated additional signal; and a different duty cycle as the estimated additional signal.

10. The method of claim 2, wherein the algorithm is a machine learning algorithm.

11. The method of claim 2, wherein each of the first analog signal and the second analog signal comprises an AC component and a DC component, and wherein the estimated target signal applying the algorithm to the first analog signal and the second analog signal comprises applying the algorithm to the AC component of the at least one of the first analog signal and the second analog signal.

12. The method of claim 2, wherein the decomposition relationship is an unmixing matrix.

13. The method of claim 1, wherein the first analog signal corresponds to a weighted mixture of energy detected from the energy reflected from the target active component, and additional energy reflected from the additional active component.

14. The method of claim 1, further comprising applying an electric signal to the DUT, wherein the electric signal causes a voltage on the target active component to be modulated over time.

15. The method of claim 1, wherein the portion of the DUT illuminated by the focused laser beam includes a plurality of additional active components, and each of the first reflected energy and the second reflected energy further comprises an individual reflected energy from each additional active components of the plurality of additional active components.

16. The method of claim 1, wherein the portion of the DUT illuminated by the focused laser beam further includes a further active component of the DUT, and the method further comprises:
detecting, by the one or more sensors, a third reflected energy from the DUT; and
generating, by the processor, a third analog signal that corresponds to the third reflected energy detected by the one or more sensors, wherein each of the first reflected energy, the second reflected energy and the third reflected energy comprises a portion of further reflected energy from the further active component.

17. The method of claim 16, further comprising:
applying an algorithm to the first analog signal, the second analog signal, and the third analog signal to generate a decomposition relationship that defines a relationship between the target reflected energy and at least one of the first analog signal, the second analog signal, and the third analog signal; and
generating, based on the decomposition relationship, the estimated target signal from at least one of the first analog signal, the second analog signal, and the third analog signal.

18. The method of claim 1, wherein determining the performance of the target active component of the DUT comprises comparing the estimated target signal to an expected reflected signal from the target active component.

19. The method of claim 17, wherein determining the performance of the target active component of the DUT comprises determining that the target active component is performing properly based on a modulation of the estimated target signal being within a threshold level of similarity with an expected modulation for the expected reflected signal from the target active component.

20. The method claim 17, wherein determining the performance of the target active component of the DUT comprises isolating an electrical failure in the DUT based on the estimated reflected signal.

21. The method claim 1, wherein the light source is a focused laser beam, the first energy is first reflected energy that is reflected by the DUT as a result of the focused laser beam being incident on the DUT, and the second energy is second reflected energy that is reflected by the DUT as a result of the focused laser beam being incident on the DUT.

22. A system for optically determining performance of components of the DUT, the system comprising:
the DUT, wherein the DUT comprises an upper layer, wherein the upper layer comprises at least the target active component and the additional active component of the DUT;
a laser source configured to cause the focused laser beam to illuminate the portion of the DUT that includes the target active component and the additional active component of the DUT;
the one or more sensors configured to detect energy reflected from at least the target active component and the additional active component of the DUT;
one or more processors; and
a memory storing non-transitory computer readable instructions that, when executed by the one or more processors, cause the one or more processors to perform the method of claim 1.
